(19) United States
(12) Patent Application Publication
(10) Pub. No.: US 2009/0051020 A1
(43) Pub. Date: Feb. 26, 2009

(54) METHOD OF MANUFACTURING SEMICONDUCTOR DEVICE, AND SEMICONDUCTOR DEVICE

(75) Inventors: Takashi Taira, Kanagawa-ken (JP); Masaru Koyanagi, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 12/035,813

(22) Filed: Feb. 22, 2008

(30) Foreign Application Priority Data
Feb. 22, 2007 (JP) 2007-042108

(51) Int. Cl. H01L 21/58; H01L 23/495

(52) U.S. Cl. 257/676; 438/123; 257/E21.499; 257/E23.031

(57) ABSTRACT

A semiconductor memory device includes: A method of manufacturing a semiconductor device, wherein a semiconductor chip is mounted on a lead frame including a plurality of lead lines, and terminals included in the semiconductor chip are connected to the lead lines, thereby to manufacture the semiconductor device, comprising the steps of:
arranging distal end parts of the plurality of lead lines at equal intervals along a direction of a first axis, the distal end parts being connected with the terminals included in the semiconductor chip;
arranging terminal parts for inputting/outputting signals, at equal intervals along a direction of a second axis;
shaping intermediate parts for connecting the distal end parts and the terminal parts, so as to be bent between the distal end parts and the terminal parts;
forming a half number of the plurality of lead lines and the remaining half number of the plurality of lead lines so as to have a shape of line symmetry with respect to the second axis; and mounting the semiconductor chip on a front surface side of a package.

### CROSS-REFERENCE TO RELATED APPLICATIONS

This application is based upon and claims the benefit of priority from the prior Japanese Patent Application No. 2007-42108, filed Feb. 22, 2007, the entire contents of which are incorporated herein by reference.

### BACKGROUND OF THE INVENTION

1. Field of the Invention

The present invention has for its object to provide a method of manufacturing a semiconductor device which can cope with any assembly technique and whose size is reduced, and such a semiconductor device.

2. Description of the Related Art

Heretofore, in case of encapsulating a semiconductor chip within a package, a configuration has been employed wherein the semiconductor chip is mounted over (or under) a lead frame. The optimal array sequence of bonding pads in the semiconductor chip is determined by such conditions as the type of the package and the method of mounting, and it differs depending upon individual conditions. Accordingly, a semiconductor chip dedicated to each package is often prepared by, for example, changing the metal layer of the semiconductor chip in accordance with the type of the package, the method of mounting and other conditions.

A TSOP (Thin Small Outline Package) is one of those packages of semiconductor chips which is used extensively. Therefore, many semiconductor manufactures adopt the TSOP. Besides, the semiconductor manufacturers often outsource the assembly process of the TSOP to assemblers in order to lower the cost of this process.

In case of outsourcing the assembly process in this manner, the selection of the assembler becomes very important. The semiconductor manufacturer wants to suppress the assembling cost as much as possible. However, if the assembler offering a low assembling cost does not have a technique required by the semiconductor manufacturer, the semiconductor manufacturer cannot adopt the assembler. Besides, an assembler which uses a special technique (for example, a technique which mounts semiconductor chips on the top and bottom of a lead frame) which exceeds the requirements of the semiconductor manufacturer, frequently demands a high price. That is, a method of manufacturing a semiconductor device which can cope with any assembly technique needs to be provided in order that the semiconductor manufacturer may suppress the assembly process cost to a minimum. Besides, when the circuit of the semiconductor chip to be encapsulated within the TSOP is configured so as to be capable of coping with any assembly process, increase the size of the semiconductor chip.

### BRIEF SUMMARY OF THE INVENTION

A method of manufacturing a semiconductor device, wherein a semiconductor chip is mounted on a lead frame including a plurality of lead lines, and terminals included in the semiconductor chip are connected to the lead lines, thereby to manufacture the semiconductor device, comprising the steps of:

arranging distal end parts of the plurality of lead lines at equal intervals along a direction of a first axis, the distal end parts being connected with the terminals included in the semiconductor chip;

arranging terminal parts for inputting/outputting signals, at equal intervals along a direction of a second axis;

shaping intermediate parts for connecting the distal end parts and the terminal parts, so as to be bent between the distal end parts and the terminal parts;

forming a half number of the plurality of lead lines and the remaining half number of the plurality of lead lines so as to have a shape of line symmetry with respect to the second axis; and

mounting the semiconductor chip on a front surface side of a package.

### BRIEF DESCRIPTION OF THE SEVERAL VIEWS OF THE DRAWING

FIG. 1 is a top view showing a semiconductor chip for use in an example of the manufacturing process of a semiconductor device;

FIG. 2 is a top view showing a lead frame for use in an example of the manufacturing process of the semiconductor device;

FIG. 3 is a side view showing the lead frame for use in the example of the manufacturing process of the semiconductor device;

FIG. 4 is a top view showing a state where the semiconductor chip is mounted on the top of the lead frame in accordance with the example of the manufacturing process of the semiconductor device;

FIG. 5 is a top view showing a state where the semiconductor chip is mounted on the bottom of the lead frame in accordance with the example of the manufacturing process of the semiconductor device;

FIG. 6 is a schematic view of a method of manufacturing a semiconductor device according to an embodiment of the present invention;

FIG. 7 is a top view showing a semiconductor chip for use in the manufacturing process of the semiconductor device according to the embodiment of the invention;

FIG. 8 is a top view showing a first lead frame for use in the manufacturing process of the semiconductor device according to the embodiment of the invention;

FIG. 9 is a top view showing a second lead frame for use in the manufacturing process of the semiconductor device according to the embodiment of the invention;

FIG. 10 is a top view showing a state where the semiconductor chip has been mounted on the bottom of the first lead frame by the manufacturing process of the semiconductor device according to the embodiment of the invention;

FIG. 11 is a side view showing the state where the semiconductor chip has been mounted on the bottom of the first lead frame by the manufacturing process of the semiconductor device according to the embodiment of the invention;

FIG. 12 is a bottom view showing the state where the semiconductor chip has been mounted on the bottom of the first lead frame by the manufacturing process of the semiconductor device according to the embodiment of the invention;

FIG. 13 is a top view showing a state where the semiconductor chip has been mounted on the top of the second lead frame by the manufacturing process of the semiconductor device according to the embodiment of the invention;

FIG. 14 is a side view showing the state where the semiconductor chip has been mounted on the top of the second lead frame by the manufacturing process of the semiconductor device according to the embodiment of the invention;

FIG. 15 is a bottom view showing the state where the semiconductor chip has been mounted on the top of the second lead frame by the manufacturing process of the semiconductor device according to the embodiment of the invention;

FIG. 16 is a top view of a semiconductor device according to an embodiment of the invention;

FIG. 17 is a side view of the semiconductor device according to the embodiment of the invention; and

FIG. 18 is a bottom view of the semiconductor device according to the embodiment of the invention.

### DETAILED DESCRIPTION OF THE INVENTION

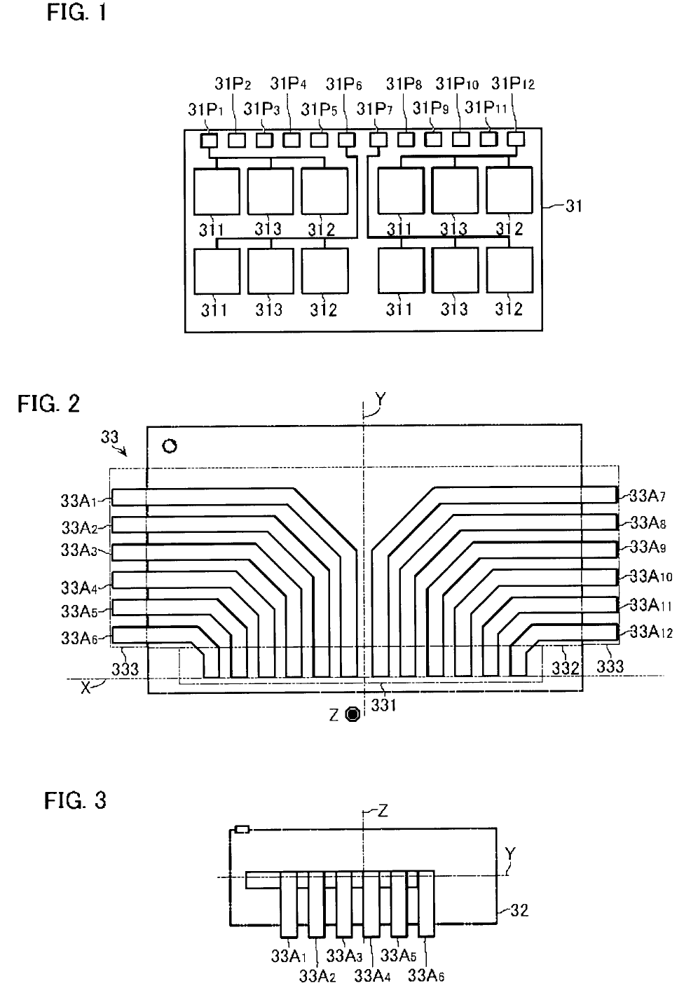

First, an example in the case where one semiconductor chip is accommodated in a TSOP package or where a plurality of semiconductor chips are stacked and accommodated in a single TSOP package will be described with reference to FIGS. 1-5.

FIG. 1 is a top view of a semiconductor chip 31, FIG. 2 is a top view of a lead frame 33, and FIG. 3 is a side view of the lead frame 33.

As shown in FIG. 1, the semiconductor chip 31 is in the shape of a rectangular plate, and twelve bonding pads 31P1-31P12 which are rectilinearly arrayed are formed in the vicinity of an end part of one surface of the semiconductor chip 31. Besides, an input circuit 311, a protection circuit 312 and an output circuit 313 are connected to each of the bonding pads 31P1, 31P6, 31P7 and 31P12 of the semiconductor chip 31. That is, each of the bonding pads 31P1, 31P6, 31P7 and 31P12 includes all of the input circuit 311, the protection circuit 312 and the output circuit 313.

As shown in FIGS. 2 and 3, an axis which extends in parallel with the lengthwise direction of the lead frame 33 is set as a first axis X, and an axis which passes through the center of the lead frame 33 and which intersects orthogonally to the first axis X is set as a second axis Y. Besides, an axis which intersects orthogonally to the first axis X and the second axis Y is set as a third axis Z. In FIG. 2, the package to be sealed is indicated by a broken line.

The lead frame 33 consists of twelve lead lines 33A1-33A12. The individual lead lines 33A1-33A12 have their distal end parts 331 arranged along the long edge of the package in parallel with the first axis X and at equal intervals, and they can be electrically connected to the bonding pads 31P1-31P12, respectively. Besides, each of the lead lines 33A1-33A12 includes an intermediate part 332 and a terminal part 333 which are joined with the distal end part 331. The intermediate part 332 is formed so as to connect the distal end part 331 and the terminal part 333, within a plane which contains the first axis X and the second axis Y. That is, the intermediate part 332 is formed so as to extend in a direction parallel to the second axis Y, from the distal end part 331, to be thereafter bent and to extend in the direction of the first axis X and reach the terminal part 333. The terminal parts 333 are arranged along the short edge of the package in parallel with the second axis Y and at equal intervals. These terminal parts 333 are formed so as to be bent in the direction of the third axis Z, namely, in a direction perpendicular to the sheet of drawing in FIG. 2, and to protrude onto the bottom side of the package.

Among the lead lines 33A1-33A12, those 33A1-33A6 have their terminal parts 333 arranged along the left short edge of the package as seen in FIG. 2, whereas those 33A7-33A12 have their terminal parts 333 arranged along the right short edge of the package. Accordingly, the lead lines 33A1-33A6 and those 33A7-33A12 are endowed with the shape of mirror symmetry with respect to the second axis Y.

Besides, the lead lines 33A1 and 33A6 function as control signal terminals to which the control signals of the semiconductor chip 31 are inputted from the terminal parts 333, and the lead lines 33A7 and 33A12 function as I/O terminals which are used for exchanging data inputted from and outputted to the terminal parts 333.

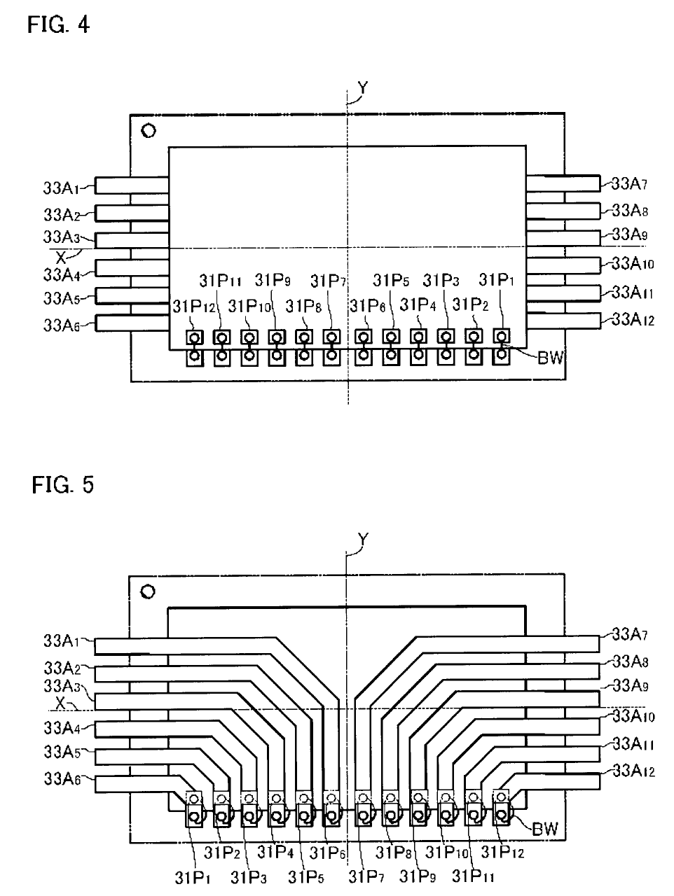

Next, there will be described a state where the semiconductor chip 31 is arranged on the top or bottom of the lead frame 33. FIG. 4 is a top view of the package in the case of employing a top arrangement technique in which the semiconductor chip 31 is mounted on the top of the lead frame 33, while FIG. 5 is a top view of the package in the case of employing a bottom arrangement technique in which the semiconductor chip 31 is mounted on the bottom of the lead frame 33. The pads 31P1-31P12, and the plurality of lead lines 33A1-33A12 are respectively connected by bonding wires BW. Incidentally, the semiconductor chip 31 and the lead frame 33 are further covered with a sealing resin from the states shown in FIGS. 4 and 5, whereby the packaging of the semiconductor chip 31 is completed.

Here, the notation 33A1(31P1) means that the lead line 33A1 is connected to the bonding pad 31P1 of the semiconductor chip 31 in FIG. 1. Then, as shown in FIG. 4, connection relations in the case where the semiconductor chip 31 is connected to the lead frame 33 as shown in FIG. 2, by employing the top arrangement technique, become 33A1(31P7), . . . , 33A6(31P12), 33A7(31P6), . . . , and 33A12(31P1).

On the other hand, connection relations in the case where the semiconductor chip 31 in FIG. 5 is connected to the lead frame 33 as shown in FIG. 2, by employing the bottom arrangement technique, become 33A1(31P6), . . . , 33A6(31P1), 33A7(31P7), . . . , and 33A12(31P12).

In this manner, in the above method for manufacturing a semiconductor device, the connection relations between the bonding pads 31P1-31P12 of the semiconductor chip and the lead lines 33A1-33A12 of the lead frame are mirrored along the second axis Y, depending upon whether the semiconductor chip is arranged on the top or bottom of the lead frame. As shown in FIG. 1, accordingly, the semiconductor chip 31 must have all of the input circuit 311, the protection circuit 312 and the output circuit 313 connected to each of the bonding pads 31P1, 31P6, 31P7 and 31P12, and the increase the size of the semiconductor chip 31 and the increase of a manufacturing cost.

Besides, in order to avoid increasing of the size, there is considered a configuration in which only the input circuit 311 and the protection circuit 312 are connected to each of the bonding pads 31P1 and 31P6 of the semiconductor chip 31, and in which the input circuit 311, the protection circuit 312 and the output circuit 313 are connected to each of the bonding pads 31P7 and 31P12, or a configuration in which the connections are opposite to the above.

However, when the semiconductor chip 31 has such a configuration, physically the distances between the bonding pads and the distal end parts of the lead lines become long, and wiring lengths therefore increase to pose the problems that the parasitic resistance of the wiring lines increases and the operating speed is reduced. Further, since the wiring lengths increase, the wiring lines are prone to come into contact, and an increase of inductance, etc. will occur.

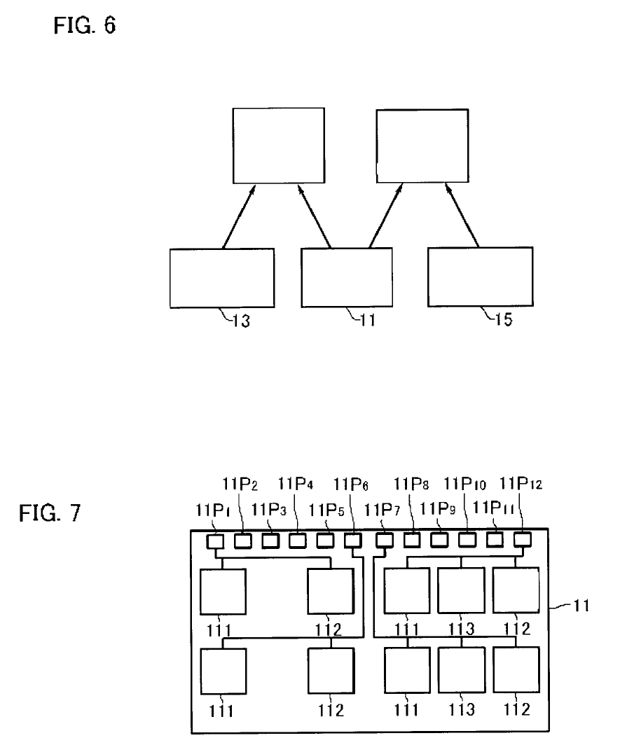

Next, a method of manufacturing a semiconductor device according to an embodiment of the present invention will be outlined with reference to FIG. 6. FIG. 6 is a schematic view of the method of manufacturing the semiconductor device according to the first embodiment.

As shown in FIG. 6, the method of manufacturing the semiconductor device according to the invention consists in manufacturing the semiconductor device by employing at least either of a first lead frame 13 and a second lead frame 15, together with a semiconductor chip 11. More specifically, in a case where the first lead frame 13 has been selected, the semiconductor chip 11 is mounted on the bottom of the first lead frame 13, and in a case where the second lead frame 15 has been selected, the semiconductor chip 11 is mounted on the top of the second lead frame 15. Now, the shapes of the semiconductor chip 11 and the first and second lead frames 13 and 15, and the connection relations thereof for attaining such a configuration will be described in detail.

FIG. 7 is a top view of the semiconductor chip 11. Incidentally, as shown in FIG. 7, the semiconductor chip 11 is in the shape of a rectangular plate, and twelve bonding pads 11p1-11P12 which are arrayed rectilinearly are formed in the vicinity of an end part of one surface of the semiconductor chip 11. Besides, an input circuit 111 and a protection circuit 112 are connected (an output circuit 113 is not connected) to each of the bonding pads 11P1 and 11P6 of the semiconductor chip 11, whereas an input circuit 111, a protection circuit 112 and an output circuit 113 are connected to each of the bonding pads 11P7 and 11P12.

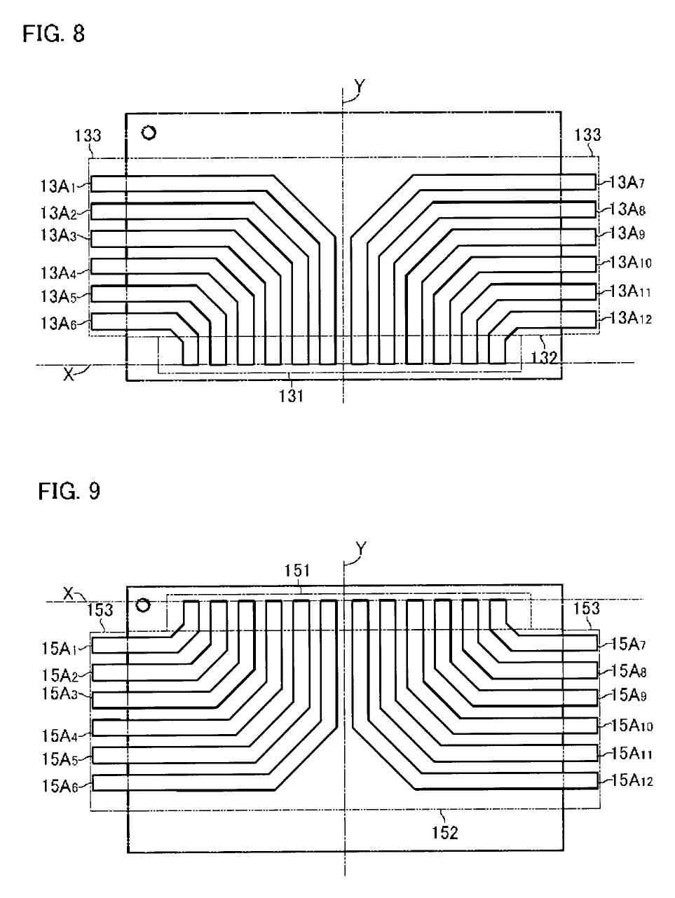

FIG. 8 is a top view of the first lead frame 13. Incidentally, a broken line in FIG. 8 indicates a package to be sealed. As shown in FIG. 8, the first lead frame 13 is configured of twelve lead lines 13A1-13A12. The first lead frame 13 has the same shape as that of the lead frame 33 shown in FIG. 2. More specifically, the individual lead lines 13A1-13A12 have their distal end parts 131 arranged along the long edge of the package in parallel with a first axis X and at equal intervals, and they can be electrically connected to the bonding pads 11P1-11P12, respectively.

Besides, each of the lead lines 13A1-13A12 includes an intermediate part 132 and the terminal part 133 which are joined with the distal end part 131. The intermediate part 132 is formed so as to connect the distal end part 131 and the terminal part 133, within a plane which contains the first axis X and a second axis Y. That is, the intermediate part 132 is formed so as to extend in a direction parallel to the second axis Y, from the distal end part 131, to be thereafter bent and to extend in the direction of the first axis X and reach the terminal part 133.

The terminal parts 133 are arranged along the short edges of the package in parallel with the second axis Y and at equal intervals. These terminal parts 133 are formed so as to be bent in the direction of a third axis Z, namely, in a direction perpendicular to the sheet of drawing in FIG. 7, and to protrude onto the bottom side of the package.

Among the lead lines 13A1-13A12, those 13A1-13A6 have their terminal parts 133 arranged along the left short edge of a package substrate 12 as seen in FIG. 8, whereas those 13A7-13A12 have their terminal parts 133 arranged along the right short edge of the package substrate 12. Accordingly, the lead lines 13A1-13A6 and those 13A7-13A12 are mirror symmetric with respect to the second axis Y.

Besides, the lead lines 13A1 and 13A6 function as control signal terminals to which the control signals of the semiconductor chip 11 are inputted from the terminal parts 133, and the lead lines 13A7 and 13A12 function as I/O terminals which are used for exchanging data inputted from and outputted to the terminal parts 133.

FIG. 9 is a top view of the second lead frame 15. Incidentally, a broken line in FIG. 9 indicates a package to be sealed. As shown in FIG. 9, the second lead frame 15 is configured of twelve lead lines 15A1-15A12. Each of the lead lines 15A1-15A12 includes an intermediate part 152 in a shape in which the intermediate part 132 of the first lead frame 13 is inverted in symmetry with respect to the first axis X. Besides, likewise to the first lead frame 13, the second lead frame 15 includes distal end parts 151 and terminal parts 153. Unlike in the first lead frame 13, the distal end parts 151 are disposed on a side opposite to the long edge of the package (namely, on the upper edge as seen in FIG. 9).

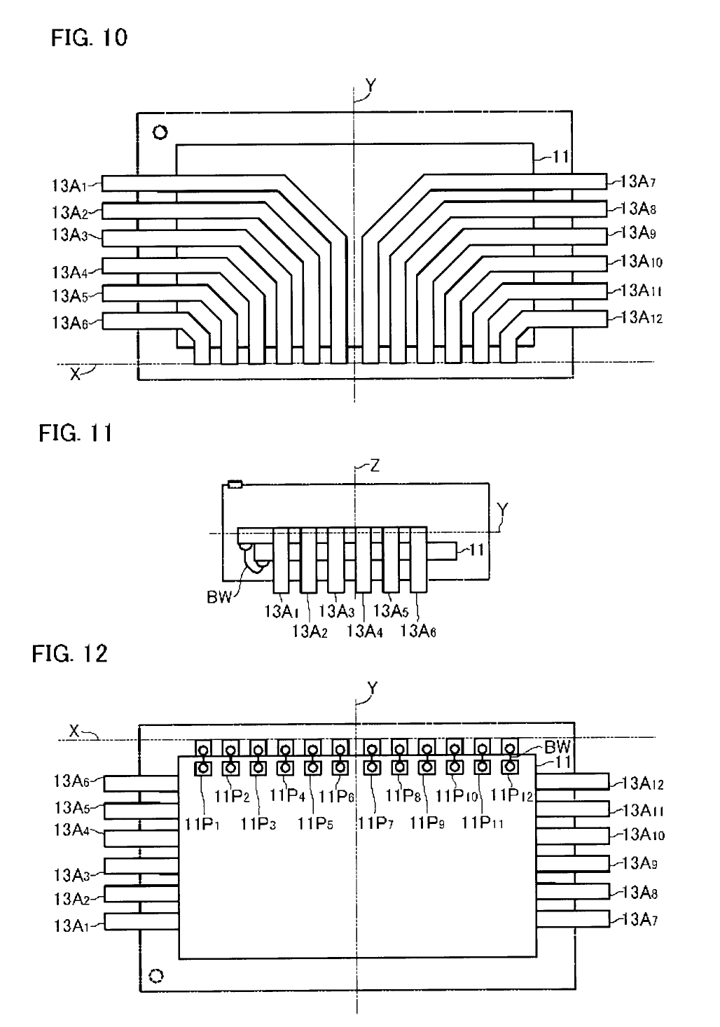

Next, a state where the semiconductor chip 11 has been arranged on the bottom of the first lead frame 13 by a bottom arrangement technique will be described with reference to FIGS. 10-12. Incidentally, broken lines in FIGS. 10 and 12 indicate the package to be sealed. FIG. 10 is a top view showing the state where the semiconductor chip 11 has been arranged on the bottom of the first lead frame 13, FIG. 11 is a corresponding side view, and FIG. 12 is a corresponding bottom view. Here, letting sign 13A1(11P6) indicate that the lead line 13A1 is connected to the bonding pad 11P6, connection relations shown in FIGS. 10-12 become 13A1(11P6), . . . , 13A6(11P1), 13A7(11P7), . . . , and 13A12(11P12).

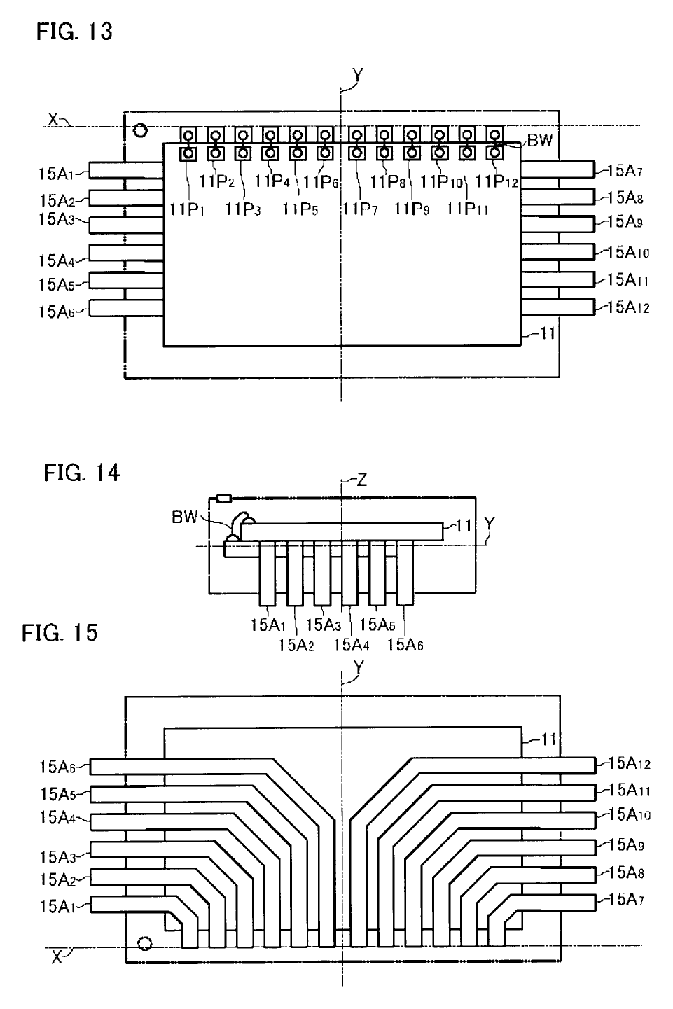

Next, a state where the semiconductor chip 11 has been arranged on the top of the second lead frame 15 by a top arrangement technique will be described with reference to FIGS. 13-15. Incidentally, broken lines in FIGS. 13 and 15 indicate the package to be sealed. FIG. 13 is a top view showing the state where the semiconductor chip 11 has been arranged on the top of the second lead frame 15, FIG. 14 is a corresponding side view, and FIG. 15 is a corresponding bottom view. Here, letting sign 15A1(11p1) indicate that the lead line 15A1 is connected to the bonding pad 11P1, connection relations shown in FIGS. 13-15 become 15A1(11P1), . . . , 15A6(11P6), 15A7(11P7), . . . , and 15A12(11P12).

As thus far described, in this embodiment, either of the first lead frame 13 and the second lead frame 15 is selected and is attached to the semiconductor chip 11, depending upon which of the bottom arrangement and the top arrangement the semiconductor chip 11 is mounted by. The first lead frame 13 and the second lead frame 15 have the shapes inverted vertically as stated above, and the connection relations between the lead lines and the corresponding bonding pads are not inverted across the second axis Y. As shown in FIG. 7, accordingly, only the input circuit 111 and the protection circuit 112 may be connected to each of the bonding pads 11P1 and 11P6 of the semiconductor chip 11. As compared with the semiconductor chip stated before, therefore, the semiconductor chip of the embodiment can omit some of the circuits, and the size of the semiconductor chip is reduced.

Incidentally, contrariwise to the above example, the semiconductor chip 11 may well be arranged on the top of the first lead frame 13 and on the bottom of the second lead frame 15.

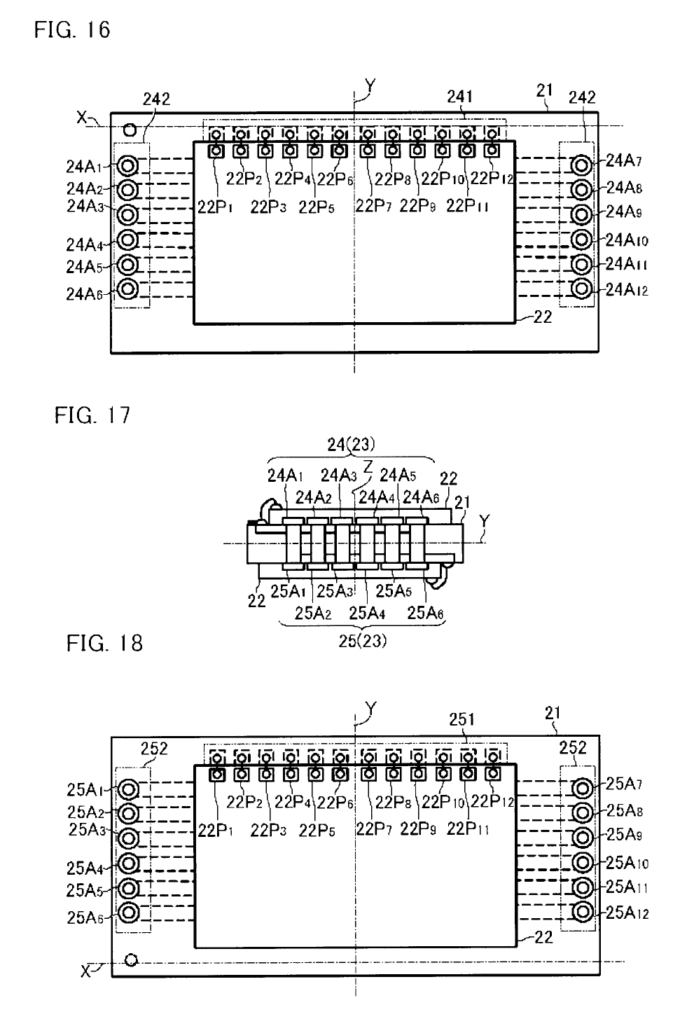

Next, a semiconductor device according to an embodiment of the invention will be described with reference to FIGS. 16-18. FIG. 16 is a top view of the semiconductor device according to the embodiment of the invention, FIG. 17 is a corresponding side view, and FIG. 18 is a corresponding bottom view.

As shown in FIGS. 16-18, the semiconductor device includes a substrate 21, semiconductor chips 22 and 22 which are disposed on both the surfaces of the substrate 21, and a lead frame 23 which is disposed in the substrate 21 and which is configured of a plurality of leads that are electrically connected to the semiconductor chips 22 and 22.

Each of the semiconductor chips 22 and 22 is in the shape of a rectangular plate, and twelve bonding pads 22P1-22P12 which are arrayed rectilinearly are formed in the vicinity of an end part of one surface of each semiconductor chip. Besides, an input circuit and a protection circuit are connected to each of the bonding pads 22P1 and 22P6 of the semiconductor chip 22, while an input circuit, a protection circuit and an output circuit are connected to each of the bonding pads 22P7 and 22P12 (omitted from illustration).

Here, an axis which extends in parallel with the lengthwise direction of the substrate 21 in the vicinity of the end part thereof is set as a first axis X, and an axis which passes through the center of the substrate 21 and which extends in parallel with a widthwise direction intersecting orthogonally to the first axis X is set as a second axis Y. Besides, an axis which intersects orthogonally to the first axis X and the second axis Y is set as a third axis Z.

The lead frame 23 consists of a first lead frame 24 and a second lead frame 25 each of which is configured of a plurality of lead lines.

As shown in FIGS. 16-18, the first lead frame 24 is configured of twelve lead lines 24A1-24A12. The individual lead lines 24A1-24A12 have their distal end parts 241 arranged on the first axis X in parallel and at equal intervals, and they are electrically connected to the bonding pads 22. Besides, the first lead frame 24 extends in a first direction parallel to the second axis Y from the distal end parts 241, within a plane containing the first axis X and the second axis Y, and it also extends in a second direction parallel to the first axis X and in a third direction opposite to the second direction, in symmetry with respect to the second axis Y, thereby to form terminal parts 242 at its terminal ends, respectively. The terminal parts 242 are formed so as to be exposed from the front surface of the substrate 21.

The second lead frame 25 is configured of twelve lead lines 25A1-25A12 which have such a shape that the lead lines of the first lead frame 24 are inverted with respect to the first axis X. Incidentally, likewise to the first lead frame 24, the second lead frame 25 includes distal end parts 251 and terminal parts 252. Besides, the distal end parts 251 of the respective lead lines 25A1-25A12 are connected to the bonding pads 22P1-22P12 of the semiconductor chip 22.

Besides, the respective lead lines 25A1-25A12 of the second lead frame 25 are connected to the corresponding lead lines 24A1-24A12 of the first lead frame 24.

As stated above, the second lead frame 25 is formed by inverting the first lead frame 24 with respect to the second axis Y, so that the connection relations between the lead frame and the semiconductor chips are not inverted astride (beyond) the second axis Y. It is accordingly permitted to provide the semiconductor device in which the semiconductor chips 22 and 22 of simplified circuit arrangement are arranged on both the surfaces of the substrate 21. Moreover, the first and second lead frames 24 and 25 are formed having small occupation areas. It is therefore permitted to provide the semiconductor device of still smaller size.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method of manufacturing a semiconductor device, wherein a semiconductor chip is mounted on a lead frame including a plurality of lead lines, and terminals included in the semiconductor chip are connected to the lead lines, thereby to manufacture the semiconductor device, comprising the steps of:
arranging distal end parts of the plurality of lead lines at equal intervals along a direction of a first axis, the distal end parts being connected with the terminals included in the semiconductor chip;
arranging terminal parts for inputting/outputting signals, at equal intervals along a direction of a second axis;
shaping intermediate parts for connecting the distal end parts and the terminal parts, so as to be bent between the distal end parts and the terminal parts;
forming a half number of the plurality of lead lines and the remaining half number of the plurality of lead lines so as to have a shape of line symmetry with respect to the second axis; and
mounting the semiconductor chip on a front surface side of a package.

2. A method of manufacturing a semiconductor device, wherein a semiconductor chip is mounted on a lead frame including a plurality of lead lines, and terminals included in the semiconductor chip are connected to the lead lines, thereby to manufacture the semiconductor device, comprising the steps of:
arranging distal end parts of the plurality of lead lines at equal intervals along a direction of a first axis, the distal end parts being connected with the terminals included in the semiconductor chip;
arranging terminal parts for inputting/outputting signals, at equal intervals along a direction of a second axis;
shaping intermediate parts for connecting the distal end parts and the terminal parts, so as to be bent between the distal end parts and the terminal parts;
forming a half number of the plurality of lead lines and the remaining half number of the plurality of lead lines so as to have a shape of line symmetry with respect to the second axis;
forming a planar shape of the plurality of lead lines of the lead frame so as to be inverted with respect to the first axis as viewed from a top side of the lead frame; and
mounting the semiconductor chip on a rear surface side of a package.

3. A semiconductor memory device comprising:
a substrate, a first semiconductor chip which is disposed on one surface of said substrate, a second semiconductor chip which is disposed on the other surface of said substrate, and a lead frame which includes a plurality of leads that are disposed in said substrate and that are electrically connected to said first semiconductor chip and said second semiconductor chip;
wherein said lead frame includes a first lead frame and a second lead frame each of which includes a plurality of lead lines;
the plurality of lead lines of said first lead frame are such that their distal end parts are arranged at equal intervals in parallel with a first axis, that their terminal end parts joined with the distal end parts are formed so as to extend in a direction parallel to a second axis orthogonal to the first axis, from the distal end parts, and to be thereafter bent and to extend in a direction of the first axis, and that a half number of the plurality of lead lines and the remaining half number of the plurality of lead lines are endowed with a shape of line symmetry with respect to the second axis; and
the plurality of lead lines of said second lead frame are such that the plurality of lead lines are formed in a shape obtained by inverting the plurality of lead lines of said first lead frame with respect to the first axis, and that the respective lead lines are connected to the corresponding lead lines of said first lead frame.
